(19) United States
(12) Patent Application Publication
(10) Pub. No.: US 2026/0145293 A1
(43) Pub. Date: May 28, 2026

(54) METHOD OF MANUFACTURING A SEMICONDUCTOR DEVICE

(71) Applicant: Kioxia Corporation, Tokyo (JP)

(72) Inventors: Kentaro SATO, Fujisawa Kanagawa (JP); Kazuyuki HINO, Yokohama Kanagawa (JP); Weiting WANG, Kawasaki Kanagawa (JP); Yayori SATO, Shinagawa Tokyo (JP)

(21) Appl. No.: 19/325,181

(22) Filed: Sep. 10, 2025

(30) Foreign Application Priority Data
Nov. 26, 2024 (JP) 2024-205737

(51) Int. Cl. B24B 37/013; B24B 37/04; G03F 7/00; H01L 21/3105; H01L 21/321

(52) U.S. Cl. CPC B24B 37/013; B24B 37/042; G03F 7/70433; G03F 7/705; H10P 52/403; H10P 95/062

(57) ABSTRACT

A method of manufacturing a semiconductor device includes acquiring a process margin of a second layer to be formed on a substrate of the semiconductor device after a first layer is formed on the substrate, based on layout data of the first layer; executing a process simulation on a computer to determine whether a condition related to the process margin of the second layer falls within an allowable range; until the condition related to the process margin of the second layer falls within the allowable range, changing the layout data of the first layer and re-executing the process simulation on the computer; forming a pattern on an original plate using the changed layout data; and transferring the pattern on the generated original plate to the substrate.

### CROSS-REFERENCE TO RELATED APPLICATION(S)

This application is based upon and claims the benefit of priority from Japanese Patent Application No. 2024-205737, filed Nov. 26, 2024, the entire contents of which are incorporated herein by reference.

### FIELD

Embodiments described herein relate generally to a method of manufacturing a semiconductor device.

### BACKGROUND

In the process of manufacturing semiconductor devices, actual patterns are formed on substrates by generating layout data with layout design, drawing patterns in accordance with the generated layout data on original plates, and transferring the patterns on the original plates to the substrates. In the process of manufacturing semiconductor devices, it is desirable to secure appropriate process margins.

### BRIEF DESCRIPTION OF THE DRAWINGS

FIG. 1 is a block diagram illustrating a configuration of a manufacturing system to which a layout generation method according to a first embodiment is applied.

FIG. 2 is a flowchart illustrating a method of manufacturing a semiconductor device including the layout generation method according to the first embodiment.

FIG. 3 is a flowchart illustrating the layout generation method according to the first embodiment.

FIG. 4 is a flowchart illustrating a layout generation method according to a second embodiment.

FIG. 5 is a diagram illustrating a concept of a CMP margin according to the second embodiment.

FIG. 6 is a flowchart illustrating an order of CMP margin calculation according to the second embodiment.

FIG. 7 is a diagram illustrating an enlarged CMP margin according to the second embodiment.

FIG. 8 is a flowchart illustrating a layout generation method according to a third embodiment.

FIG. 9 is a diagram illustrating an enlarged lithographic margin relative to a required lithographic margin according to the third embodiment.

FIGS. 10A to 10D are diagrams illustrating a change in layout of a current layer according to the third embodiment.

FIG. 11 is a flowchart illustrating a layout generation method according to a fourth embodiment.

FIGS. 12A and 12B are diagrams illustrating a margin curve in each region according to the fourth embodiment.

### DETAILED DESCRIPTION

Embodiments provide a method of manufacturing a semiconductor device that is capable of securing an appropriate process margin.

In general, according to one embodiment, a method of manufacturing a semiconductor device includes acquiring a process margin of a second layer to be formed on a substrate of the semiconductor device after a first layer is formed on the substrate, based on layout data of a first layer; executing a process simulation on a computer to determine whether a condition related to the process margin of the second layer falls within an allowable range; until the condition related to the process margin of the second layer falls within the allowable range, changing the layout data of the first layer and re-executing the process simulation on the computer; forming a pattern on an original plate using the changed layout data; and transferring the pattern on the generated original plate to the substrate.

Hereinafter, a layout generation method according to embodiments will be described in detail with reference to the appended drawings. The scope of the present disclosure is not limited by the embodiments.

### First Embodiment

In a layout generation method according to a first embodiment, layout data to be used to manufacture a semiconductor device is generated. Measures are taken to secure an appropriate process margin in the process of manufacturing a semiconductor device.

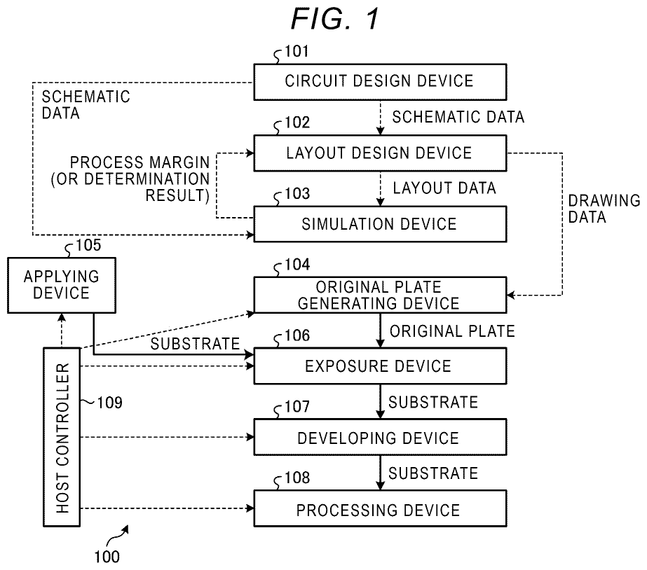

The layout generation method may be applied to a manufacturing system 100 illustrated in FIG. 1. FIG. 1 is a block diagram illustrating a configuration of the manufacturing system 100 to which the layout generation method is applied.

The manufacturing system 100 includes a circuit design device 101, a layout design device 102, a simulation device 103, an original plate generating device 104, an applying device 105, an exposure device 106, a developing device 107, a processing device 108, and a host controller 109. The circuit design device 101, the layout design device 102, and the simulation device 103 may be implemented on one computer or may be implemented on a plurality of computers connected to be able to communicate with each other. An example of the original plate generating device 104 is an electron beam lithography device. The circuit design device 101, the layout design device 102, the simulation device 103, and the original plate generating device 104 are connected to be able to communicate with each other via communication line (not illustrated). The simulation device 103, the applying device 105, the exposure device 106, the developing device 107, the processing device 108, and the host controller 109 are connected to be able to communicate with each other via communication line (not illustrated).

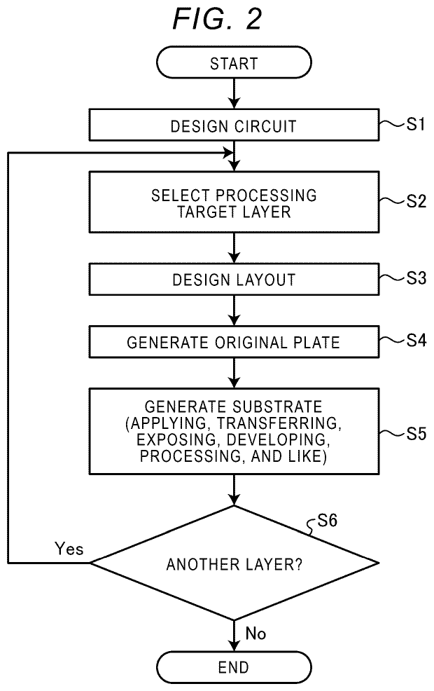

The manufacturing system 100 operates as illustrated in FIG. 2. FIG. 2 is a flowchart illustrating an operation of the manufacturing system 100.

The circuit design device 101 executes circuit design based on predetermined design information and/or an instruction from a user (S1) to generate schematic data and supply the generated schematic data to the layout design device 102.

Since a device in accordance with schematic data can be implemented with a structure with a plurality of layers, layout design is also executed for the plurality of layers in a manufacturing order. The layout design device 102 selects a processing target layer as a current layer among the plurality of layers (S2).

The layout design device 102 executes layout design based on the schematic data and/or an instruction from the user in cooperation with the simulation device 103 (S3) to generate a layout of the current layer.

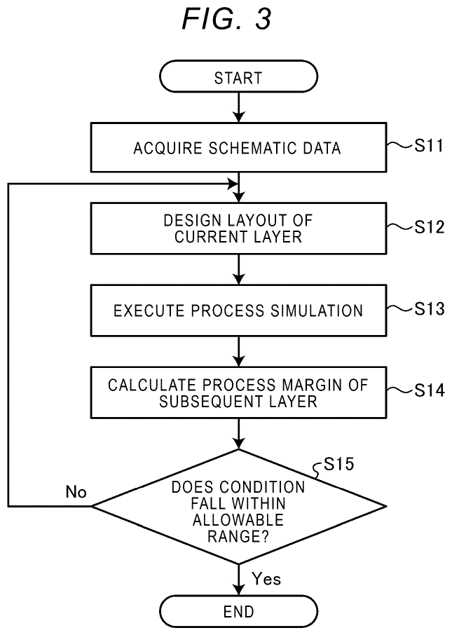

In S3, the layout design illustrated in FIG. 3 may be executed. FIG. 3 is a flowchart illustrating a layout generation method.

When the schematic data is acquired from the circuit design device 101 (S11), the layout design device 102 executes layout design of the current layer (S12). The layout design device 102 arranges a plurality of patterns in accordance with the schematic data on a layout diagram of the current layer. Accordingly, the layout design device 102 generates the layout data of the current layer and supplies the generated layout data to the simulation device 103.

The simulation device 103 executes a process simulation using the layout data of the current layer (S13).

The simulation device 103 may simulate a processing shape of the substrate when a semiconductor process (for example, applying, transferring, exposing, developing, processing, and the like) is executed on the substrate, or may simulate processing conditions of the substrate when semiconductor process is executed on the substrate.

The simulation device 103 may verify whether design of a layout diagram matches design of a schematic diagram or may verify whether a physical design standard (design rule) is satisfied (design rule checking).

The simulation device 103 calculates a process margin of a subsequent layer to be formed after the current layer in accordance with a simulation result and a verification result (S14). The simulation device 103 may numerically calculate the process margin of the subsequent layer. The simulation device 103 may numerically calculate a required process margin in accordance with a plurality of patterns of the subsequent layer. The simulation device 103 supplies the layout design device 102 with the process margin of the subsequent layer or the required process margin of the subsequent layer.

When the process margin of the subsequent layer or the required process margin of the subsequent layer is supplied, the layout design device 102 determines whether a condition related to the process margin of the subsequent layer falls within an allowable range (S15). The layout design device 102 may determine whether a processing shape of the substrate satisfies the process margin when the semiconductor process is executed on the substrate, may determine whether the processing condition of the substrate satisfies the process margin when the semiconductor process is executed on the substrate, or may determine whether the required process margin in accordance with the plurality of patterns of the subsequent layer satisfies the process margin.

When the condition related to the process margin of the subsequent layer does not fall within the allowable range (No in S15), the layout design device 102 returns the process to S12, executes the layout design of the current layer again (S12), and changes the layout data of the current layer. The layout design device 102 supplies the changed layout data of the current layer to the simulation device 103.

The simulation device 103 executes the process simulation and the verification using the changed layout data of the current layer (S13) and calculates the process margin of the subsequent layer to be formed after the current layer again according to the simulation result and the verification result (S14). The simulation device 103 supplies the process margin of the subsequent layer to the layout design device 102.

when the process margin of the subsequent layer is supplied, the layout design device 102 determines whether the condition related to the process margin of the subsequent layer falls within the allowable range (S15).

A loop process of S12 to S15 is repeated until the condition related to the process margin of the subsequent layer falls within the allowable range (No in S15).

When it is confirmed that the condition related to the process margin of the subsequent layer falls within the allowable range (Yes in S15) and the layout of the current layer satisfies a design rule in the design rule checking, the layout design device 102 ends the layout design of the current layer.

When the layout design of the current layer ends, the layout design device 102 generates drawing data from the layout data of the current layer and supplies the generated drawing data to the original plate generating device 104. The original plate is, for example, a mask, a reticle, or the like.

The original plate generating device 104 draws a plurality of original plate patterns on an original plate substrate according to the drawing data and generates an original plate (S4). The generated original plate can be set in an original plate stage of the applying device 105.

Thereafter, a substrate is generated (S5).

For example, the applying device 105 applies a photosensitive agent (for example, a resist) to a substrate (for example, a wafer). The substrate to which the photosensitive agent is applied is conveyed from the applying device 105 to the exposure device 106 by a conveyance system (not illustrated) and is placed on a substrate stage of the exposure device 106. The exposure device 106 irradiates the original plate with an illumination optical system and the exposure light transmitted through the original plate or reflected by the original plate is imaged on the substrate by a projection optical system, to thereby transfer the plurality of patterns on the original plate to the photosensitive agent on the substrate to form a latent image.

The substrate after the exposure is conveyed from the exposure device 106 to the developing device 107 by a conveyance system (not illustrated). The developing device 107 develops the latent image in the photosensitizer on the substrate. Accordingly, a pattern in accordance with design information (drawing data) is developed in each shot region on the substrate.

The substrate after the developing is conveyed from the developing device 107 to the processing device 108 by a conveyance system (not illustrated). The processing device 108 executes predetermined processing on the substrate using the developed pattern of the photosensitizer as a mask. Accordingly, the pattern in accordance with the design information (drawing data) is formed in each shot region on the substrate.

The system 100 returns the process to S2 when there is another layer to be processed among the plurality of layers for implementing a device in accordance with the schematic data (Yes in S6).

The system 100 ends the process when there is no other layer to be processed (No in S6).

As described above, in the layout generation method according to the first embodiment, the process margin of a subsequent layer is obtained using the layout data of the current layer, it is determined whether the condition related to the process margin of the subsequent layer falls within the allowable range, and the layout data of the current layer is changed when the condition does not fall within the allowable range. These processes are repeated until the condition related to the process margin of the subsequent layer falls within the allowable range. Accordingly, the layout design of the subsequent layer can be executed so that the process margin is secured. That is, it is possible to secure an appropriate process margin.

The determination of S15 illustrated in FIG. 3 may be executed by the simulation device 103. In this case, after the process margin of the subsequent layer is calculated (S14), the simulation device 103 determines whether the condition related to the process margin of the subsequent layer falls within the allowable range (S15), and supplies the determination result to the layout design device 102. The layout generation method itself is similar to that of the first embodiment.

### Second Embodiment

Next, a layout generation method according to a second embodiment will be described. Hereinafter, differences from the first embodiment will be described mainly.

In the first embodiment, the process of executing the process simulation using the layout data of the current layer and obtaining the process margin of the subsequent layer is illustrated. In the second embodiment, a process of executing a chemical mechanical polishing (CMP) simulation using the layout data of the current layer and obtaining a CMP margin of the subsequent layer will be illustrated.

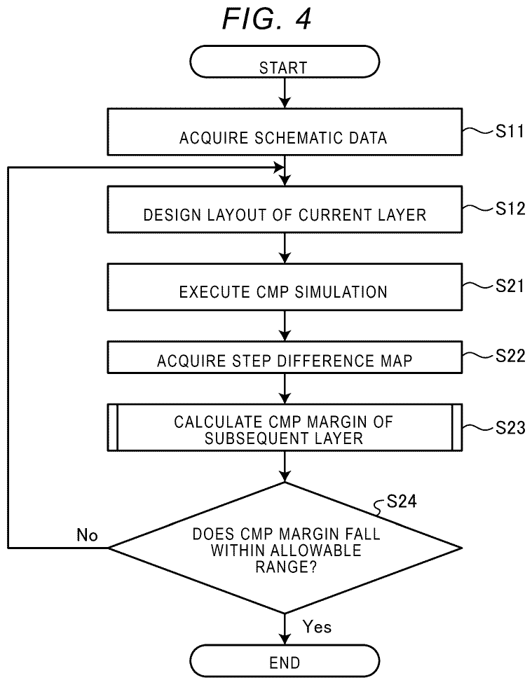

In S3 of FIG. 2, as illustrated in FIG. 4, layout design different from that of the first embodiment may be executed at a subsequent point. FIG. 4 is a flowchart illustrating a layout generation method according to the second embodiment.

After S11 and S12 are executed similarly to the first embodiment, the simulation device 103 executes a CMP simulation using the layout data of the current layer (S21).

In the simulation device 103, library information indicating a polishing condition in accordance with layouts of a plurality of patterns is determined in advance experimentally and set. The layouts of the plurality of patterns include layouts in which a disposition density of the patterns, a maximum value of a density difference between the patterns, lengths of the patterns, widths of the patterns, and circumferential lengths of the patterns are different. The polishing condition includes a polishing rate, a polishing time, a polishing amount, a polishing shape, and the like.

The simulation device 103 executes the CMP simulation using the layout data of the current layer with reference to the library information. The simulation device 103 may execute the CMP simulation using the layout data of the current layer for a plurality of different polishing times (or a plurality of different polishing amounts).

The simulation device 103 acquires a step difference map of the subsequent layer as a simulation result (S22). The simulation device 103 may acquire the step difference map for the plurality of different polishing times (or the plurality of different polishing amounts).

The step difference map is a map 3-dimensionally indicating a shape of a polishing surface of the substrate after the CMP process. The step difference map may be configured as image data. In the step difference map, a pixel position and height information may be 2-dimensionally associated with a plurality of pixels. The step difference map may be a map in which a height of the polishing surface is 2-dimensionally indicated as light and shade or color.

The step difference map may further indicate a layout shape of a conductive film, a film thickness distribution of a conductive film, a layout shape of an insulating film, or a film thickness distribution of an insulating film. In the step difference map, a pixel position and film thickness information of a conductive film or an insulating film may be 2-dimensionally associated with a plurality of pixels.

The simulation device 103 calculates the CMP margin of the subsequent layer using the step difference map (S23). The simulation device 103 may calculate the CMP margin of the subsequent layer using a plurality of step difference maps for the plurality of different polishing times (or the plurality of different polishing amounts).

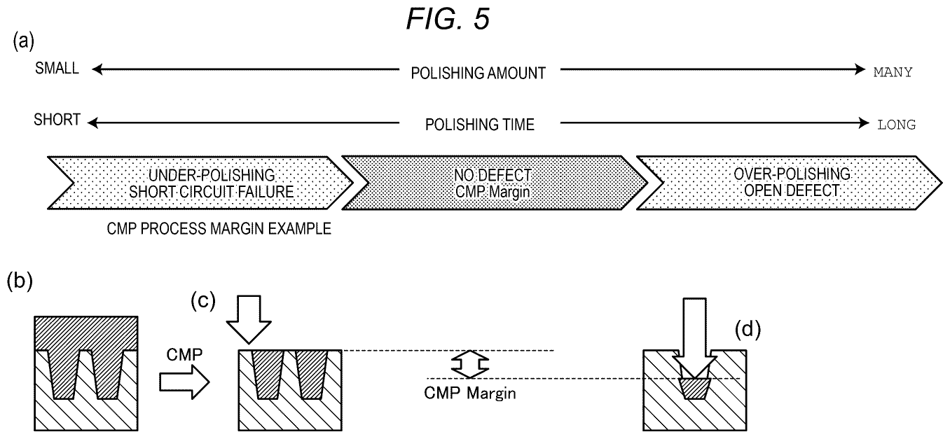

Here, the CMP margin can be defined as illustrated in FIG. 5. FIG. 5 is a diagram illustrating a concept of the CMP margin.

For example, when the CMP process is executed on the substrate and a polishing amount or a polishing time of the substrate is appropriate, a pattern of a conductive film and a pattern of an insulating film are appropriately formed and a defect does not occur. For the polishing amount or the polishing time of the substrate, as illustrated in (a) of FIG. 5, there is an appropriate range in which no defect occurs. The appropriate range in which no defect occurs for the polishing amount or the polishing time is referred to as a CMP margin.

When the polishing amount of the substrate is smaller than the appropriate range or the polishing time of the substrate is shorter than the appropriate range, as illustrated in (b) of FIG. 5, polishing of the CMP process is insufficient, under-polishing may occur in the conductive film, and a short circuit failure may occur. The short circuit failure may occur when a conductive film pattern is connected at a portion where the conductive film pattern should not be connected.

As illustrated in (c) of FIG. 5, an upper limit of the CMP margin corresponds to a polishing amount or a polishing time at which insufficient polishing starts to disappear when the polishing amount or the polishing time increases from a polishing insufficient state.

Conversely, when the polishing amount of the substrate is more than the appropriate range or the polishing time of the substrate is longer than the appropriate range, over-polishing may occur in the CMP process, excessive polishing of a conductive film occurs, and an open defect may occur. The open defect can occur when a conductive film pattern is cut at a portion where the conductive film pattern should be connected.

As illustrated in (d) of FIG. 5, a lower limit of the CMP margin corresponds to a polishing amount or a polishing time at which over-polishing starts to disappear when the polishing amount or the polishing time decreases from an excessive polishing state.

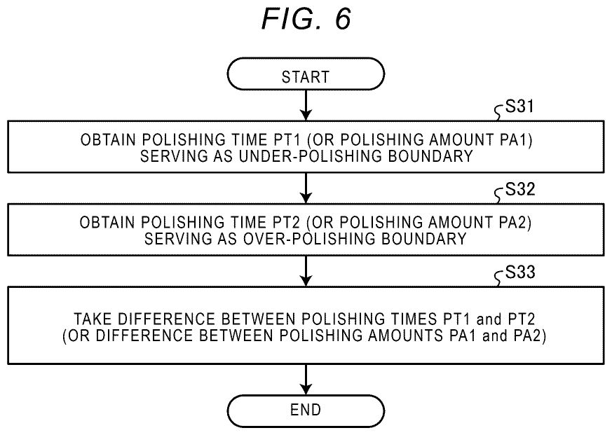

In consideration of this, in S23, the CMP margin of the subsequent layer illustrated in FIG. 6 may be calculated. FIG. 6 is a flowchart illustrating an order of the CMP margin calculation.

The simulation device 103 obtains a polishing time PT1 (or a polishing amount PA1) serving as an under-polishing boundary using the plurality of step difference maps acquired in S22 (S31).

For example, it is assumed that under-polishing occurs in at least one portion in the substrate in the step difference map of a polishing time PT10 (or a polishing amount PA10) among the plurality of step difference maps acquired in S22 and there is no portion in which under-polishing occurs in the substrate in the step difference map of a polishing time PT11 (or a polishing amount PA11). In this case, the simulation device 103 may obtain the polishing time PT1 serving as an under-polishing boundary by the following Formula 1.

$$PT 1 = ( PT 10 + PT 11 ) / 2 \qquad Formula 1$$

The simulation device 103 may obtain the polishing amount PA1 serving as the under-polishing boundary by the following Formula 2.

$$PA 1 = ( PA 10 + PA 11 ) / 2 \qquad Formula 2$$

The simulation device 103 obtains a polishing time PT2 (or a polishing amount PA2) serving as an over-polishing boundary using the plurality of step difference maps acquired in S22 (S32).

For example, it is assumed that over-polishing occurs in at least one portion in the substrate in the step difference map of a polishing time PT20 (or a polishing amount PA20) among the plurality of step difference maps acquired in S22 and there is no portion in which over-polishing occurs in the substrate in the step difference map of a polishing time PT21 (or a polishing amount PA21). In this case, the simulation device 103 may obtain the polishing time PT2 serving as an over-polishing boundary by the following Formula 3.

$$PT 2 = ( PT 20 + PT 21 ) / 2 \qquad Formula 3$$

The simulation device 103 may obtain the polishing amount PA2 serving as an over-polishing boundary by the following Formula 4.

$$PA 2 = ( PA 20 + PA 21 ) / 2 \qquad Formula 4$$

The simulation device 103 takes a difference between the polishing time PT1 and the polishing time PT2 (or a difference between the polishing amount PA1 and the polishing amount PA2 (S33) and obtains a CMP margin TM (or AM). The simulation device 103 may obtain the CMP margin TM for the polishing time by the following Formula 5.

$$TM = PT 1 - PT 2 \qquad Formula 5$$

The simulation device 103 may obtain a CMP margin AM for the polishing amount by the following Formula 6.

$$AM = PA 1 - PA 2 \qquad Formula 6$$

When the calculation (S23) of the CMP margin of the subsequent layer is completed, the simulation device 103 supplies the CMP margin of the subsequent layer to the layout design device 102.

When the CMP margin of the subsequent layer is supplied, the layout design device 102 determines whether the CMP margin of the subsequent layer falls within the allowable range (S24).

When the condition related to the process margin of the subsequent layer does not fall within the allowable range (No in S24), the layout design device 102 returns the process to S12, executes the layout design of the current layer again (S12) and changes the layout data of the current layer.

For example, the layout design device 102 may arrange a dummy pattern in a portion in which a height is low on the layout diagram among a plurality of portions in which a step difference is large on the step difference map. The layout design device 102 may increase a width and/or a size of a pattern in the portion in which the height is low on the layout diagram among the plurality of portions in which a step difference is large on the step difference map. The layout design device 102 may change a pattern shape of the portion in which the height is low on the layout diagram among the plurality of portions in which a step difference is large on the step difference map, to a further isotropic shape.

The layout design device 102 may execute disposition change to bring a disposition density of a pattern closer between a plurality of portions on the layout diagram among the plurality of portions in which a step difference is large on the step difference map. The layout design device 102 may execute the change to bring the width and/or the size of the pattern closer between the plurality of portions on the layout diagram among the plurality of portions in which a step difference is large on the step difference map. The layout design device 102 may execute the change to bring pattern shapes closer between the plurality of portions on the layout diagram.

The layout design device 102 supplies the changed layout data of the current layer to the simulation device 103.

The simulation device 103 executes the CMP simulation using the changed layout data of the current layer (S21) and acquires the step difference map again as a simulation result (S22). The simulation device 103 may acquire the step difference map for a plurality of different polishing times (or a plurality of different polishing amount).

The simulation device 103 calculates the CMP margin of the subsequent layer again using the step difference map (S23). The simulation device 103 may calculate the CMP margin of the subsequent layer using a plurality of step difference maps for a plurality of different polishing times (or a plurality of different polishing amounts).

The simulation device 103 supplies the process margin of the subsequent layer to the layout design device 102.

When the CMP margin of the subsequent layer is supplied, the layout design device 102 determines again whether the CMP margin of the subsequent layer falls within the allowable range (S24).

A loop process of S12 to S24 is repeated until the CMP margin of the subsequent layer falls within the allowable range (No in S24).

When the CMP margin of the subsequent layer falls within the allowable range (Yes in S24) and it is confirmed that the layout of the current layer satisfies a design rule by design rule checking, the layout design device 102 ends the layout design of the current layer.

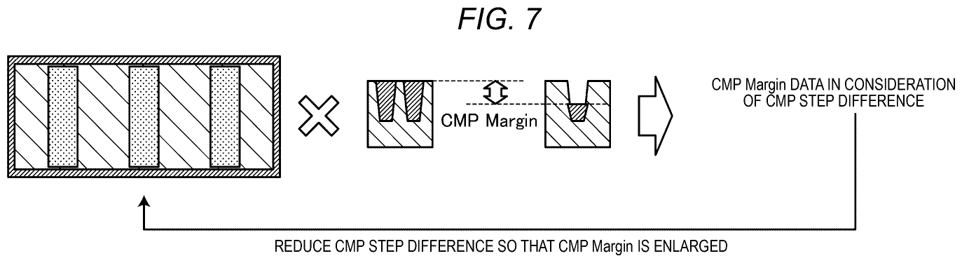

That is, by repeating the loop process of S12 to S24, as illustrated in FIG. 7, the pattern change of the current layer is repeated so that a CMP step difference is reduced, and thus the CMP step difference can be reduced and the CMP margin can be enlarged. FIG. 7 is a diagram illustrating an enlarged CMP margin.

As described above, in layout generation method according to the second embodiment, the CMP margin of the subsequent layer is obtained using the layout data of the current layer, it is determined whether the CMP margin of the subsequent layer falls within the allowable range. When the CMP margin does not fall within the allowable range, the layout data of the current layer is changed. These processes are repeated until the CMP margin of the subsequent layer falls within the allowable range. Accordingly, the layout design of the subsequent layer can be executed so that the CMP step difference is reduced and the CMP margin is secured. That is, it is possible to secure an appropriate CMP margin.

### Third Embodiment

Next, a layout generation method according to a third embodiment will be described. Hereinafter, differences from the first and second embodiments will be described mainly.

In the second embodiment, a process of enlarging the CMP margin is illustrated. In the third embodiment, a process of enlarging a lithographic margin will be illustrated.

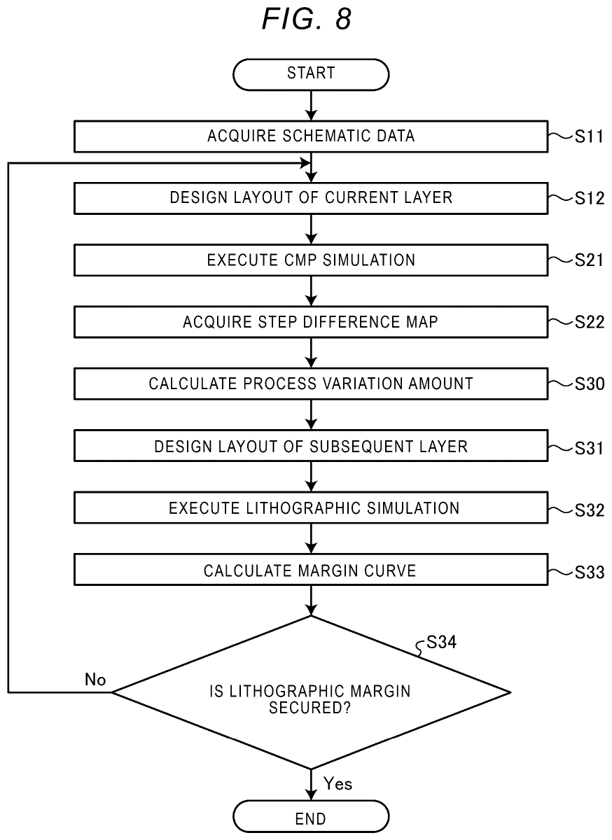

In S3 of FIG. 2, as illustrated in FIG. 8, layout design different from that of the second embodiment may be executed at a subsequent point. FIG. 8 is a flowchart illustrating a layout generation method according to the third embodiment.

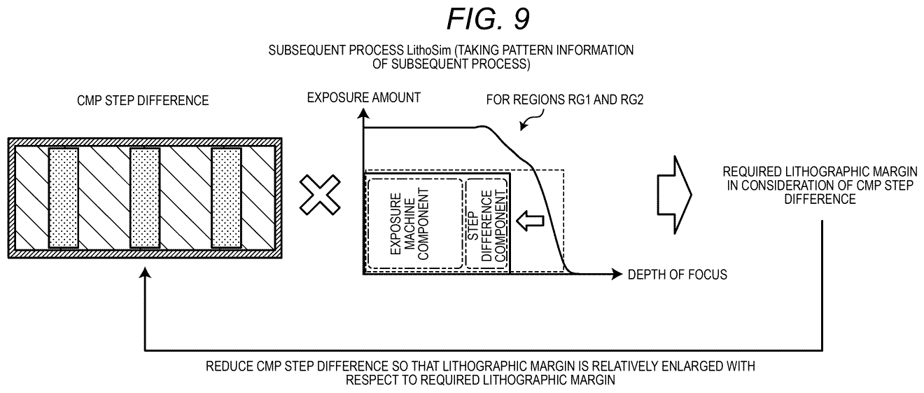

After S11 to S22 are executed similarly to the second embodiment, the simulation device 103 executes calculation of a process variation amount (S30). The process variation amount can be indicated with a rectangle that has the required exposure amount EL and the required DOF as vertices of axes on a scatter diagram that has the exposure amount EL as the vertical axis and the depth of focus DOF as the horizontal axis, as illustrated in the middle of FIG. 9. The required EL is calculated from performance of the exposure device or a variation in each process, and the required DOF is calculated from an exposure machine component and a step difference component. The exposure machine component is calculated from the performance of the exposure device, and it is difficult to make an improvement, that is, decrease this value. However, the step difference component results from a step difference of the current layer during exposure and can be decreased by alleviating the step difference.

When the calculation (S30) of the process variation amount is completed, the simulation device 103 supplies the process variation amount to the layout design device 102.

The layout design device 102 executes the layout design of the subsequent layer (S31). The layout design device 102 arranges a plurality of patterns in accordance with the schematic data on the layout diagram of the subsequent layer. Accordingly, the layout design device 102 generates the layout data of the subsequent layer and supplies the generated layout data to the simulation device 103.

The simulation device 103 executes lithographic simulation in accordance with the step difference map and the layout data of the subsequent layer (S32). The simulation device 103 may obtain an imaging feature of a pattern on the substrate with respect to an original plate pattern in accordance with the layout data of the subsequent layer. The simulation device 103 may obtain an imaging feature of the pattern on the substrate of the original plate pattern in a plurality of different exposure conditions and generate a plurality of lithographic simulation results. The plurality of exposure conditions are different from each other in at least one of the exposure amount EL and the depth of focus DOF.

The simulation device 103 calculates a margin curve of each pattern in the layout based on the performance of the exposure device 106 and the layout data (S33). The simulation device 103 can obtain a margin curve that has an exposure amount and a depth of focus as axes in accordance with the plurality of lithographic simulation results. The margin curve varies depending on a pattern, a step difference condition, or the like of the current layer. The pattern that has a minimum region surrounded by the inside of a curve indicated by a solid line illustrated at the center of FIG. 9, the vertical axis, and the horizontal axis, is also referred to as a worst pattern.

As illustrated in the middle of FIG. 9, on the scatter diagram that has the exposure amount as the horizontal axis and the depth of focus as the vertical axis, the lithographic margin is indicated as a reduction in the process variation amount from the region surrounded by the inside of the curve indicated by the solid line, the vertical axis, and the horizontal axis in the worst pattern. FIG. 9 is a diagram illustrating relative enlargement of a region (a region of the margin curve) surrounded by the margin curve, the vertical axis, and the horizontal axis with respect to the process variation amount, that is, relative enlargement of the lithographic margin with respect to the required lithographic margin.

When the calculation (S33) of the margin curve is completed, the simulation device 103 supplies the margin curve to the layout design device 102.

When the margin curve is supplied, the layout design device 102 determines whether the lithographic margin is secured according to whether the process variation amount falls within the region of the margin curve (S34).

For example, as illustrated in a rectangular region indicated by a dotted line in the middle of FIG. 9, when the process variation amount exceeds from the region of the margin curve, the layout design device 102 determines that the process variation amount does not fall within the region of the margin curve. This indicates that the lithographic margin is not secured.

When the lithographic margin is not secured (No in S34), the layout design device 102 returns the process to S12, re-executes the layout design of the current layer (S12), and changes the layout data of the current layer. Specifically, a step difference component in the required DOF is decreased by changing the layout of the current layer so that the step difference of the current layer is reduced.

For example, the layout design device 102 may arrange a dummy pattern in a portion in which a height is low on the layout diagram in a plurality of portions in which the step difference is large on the step difference map.

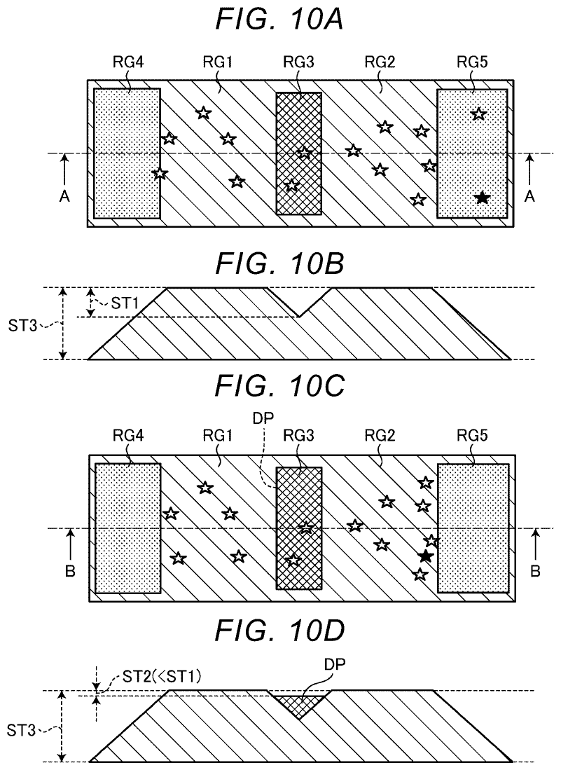

Based on the step difference map, the layout design device 102 identifies a region RG3 where a height is lower in the step difference ST1 relative to main regions RG1 and RG2 in the subsequent layer as illustrated in FIGS. 10A and 10B. FIGS. 10A to 10D are diagrams illustrating a change in layout of the current layer. FIG. 10A is a plan view illustrating the layout of the current layer before change and FIG. 10B is a sectional view illustrating the layout of the current layer before change and illustrates a cross-section taken along the line A-A of FIG. 10A.

The layout design device 102 arranges a dummy pattern DP in the region RG3, as illustrated in FIGS. 10C and 10D. FIG. 10C is a plan view illustrating the changed layout of the current layer and FIG. 10D is a sectional view illustrating the changed layout of the current layer and illustrates a cross-section taken along the line B-B of FIG. 10C. In the disposition of the dummy pattern DP, a step difference of the region RG3 with respect to the main regions RG1 and RG2 can be reduced from ST1 to ST2. Accordingly, it is conceivable that the CMP step difference can be reduced.

The layout design device 102 may enlarge a width and/or a size of a pattern in a portion in which a height is low on the layout diagram among the plurality of portions in which a step difference is large on the step difference map. The layout design device 102 may change a pattern shape of the portion in which the height is low on the layout diagram among the plurality of portions in which a step difference is large on the step difference map, to a further isotropic shape.

The layout design device 102 may execute a change to bring a disposition density of a pattern closer between a plurality of portions on the layout diagram among the plurality of portions in which a step difference is large on the step difference map. The layout design device 102 may execute the change to bring the width and/or the size of the pattern closer between the plurality of portions on the layout diagram among the plurality of portions in which a step difference is large on the step difference map. The layout design device 102 may execute the change to bring the shapes of the patterns closer between the plurality of portions on the layout diagram.

The layout design device 102 supplies the changed layout data of the current layer to the simulation device 103.

The simulation device 103 executes the CMP simulation using the changed layout data of the current layer (S21) and acquires the step difference map again as a simulation result (S22). The simulation device 103 may acquire the step difference map for a plurality of different polishing times (or a plurality of different polishing amount).

The simulation device 103 calculates the process variation amount (S30).

When the calculation of the process variation amount (S30) is completed, the simulation device 103 supplies the process variation amount to the layout design device 102.

The layout design device 102 executes the layout design of the subsequent layer again (S31) and changes the layout data of the subsequent layer.

The layout design device 102 supplies the changed layout data of the subsequent layer to the simulation device 103.

The simulation device 103 executes the lithographic simulation in accordance with the layout data of the subsequent layer and calculates the margin curve at each pattern (S32).

The simulation device 103 calculates again the margin curve in accordance with a lithographic simulation result (S33).

When the calculation of the margin curve (S33) is completed, the simulation device 103 supplies the margin curve to the layout design device 102.

When the margin curve is supplied, the layout design device 102 determines again whether the lithographic margin is secured (S34).

A loop process of S12 to S34 is repeated until the process variation amount falls within a region of the margin curve (No in S34).

For example, when the step difference component of the required DOF is decreased due to the layout change of the current layer, as illustrated in a rectangular region indicated by a solid line in the middle of FIG. 9, the right side of the process variation amount is moved to the left. When the process variation amount falls within the region of the margin curve, the layout design device 102 determines that the lithographic margin is secured.

When the process variation amount falls within the region of the margin curve (Yes in S34) and it is confirmed that the layout of the current layer satisfies the design rule by design rule checking, the layout design device 102 ends the layout design of the current layer.

That is, by repeating the loop process of S12 to S34, as illustrated in FIG. 9, the pattern change of the current layer is repeatedly executed so that the CMP step difference is reduced and the step difference component is decreased. Accordingly, the step difference component can be decreased, the required DOF can be decreased so that the process variation amount falls within the region of the margin curve, and the region of the margin curve can be enlarged relative to the process variation amount. FIG. 9 is a diagram illustrating relative enlargement of the margin curve with respect to the process variation amount, that is, relative enlargement of the lithographic margin with respect to the required lithographic margin.

By relatively enlarging the region of the margin curve with respect to the process variation amount, it is possible to arrange a pattern of a relatively thin line width LW1 even in the region RG3 in the case illustrated in FIGS. 10C and 10D. Accordingly, it is possible to reduce a chip area of a semiconductor device manufactured in accordance with the layout data.

As described above, in the layout generation method according to the third embodiment, the process variation amount is obtained in accordance with the step difference map of the subsequent layer obtained using the layout data of the current layer and the layout data of the subsequent layer. It is determined whether the process variation amount falls within the region of the margin curve. When the process variation amount does not fall within the region of the margin curve, the layout data of the current layer is changed. These processes are repeated until the process variation amount falls within the region of the margin curve. Accordingly, the layout design of the subsequent layer can be executed so that the CMP step difference is reduced and the region of the margin curve is relatively enlarged with respect to the process variation amount. That is, it is possible to secure an appropriate lithographic margin.

### Fourth Embodiment

Next, a layout generation method according to a fourth embodiment will be described. Hereinafter, differences from the first to third embodiments will be described mainly.

In the first to third embodiments, the process of obtaining a common process margin to a substrate is illustrated. In the fourth embodiment, a process of obtaining the process margin in each of a plurality of regions in a substrate will be illustrated.

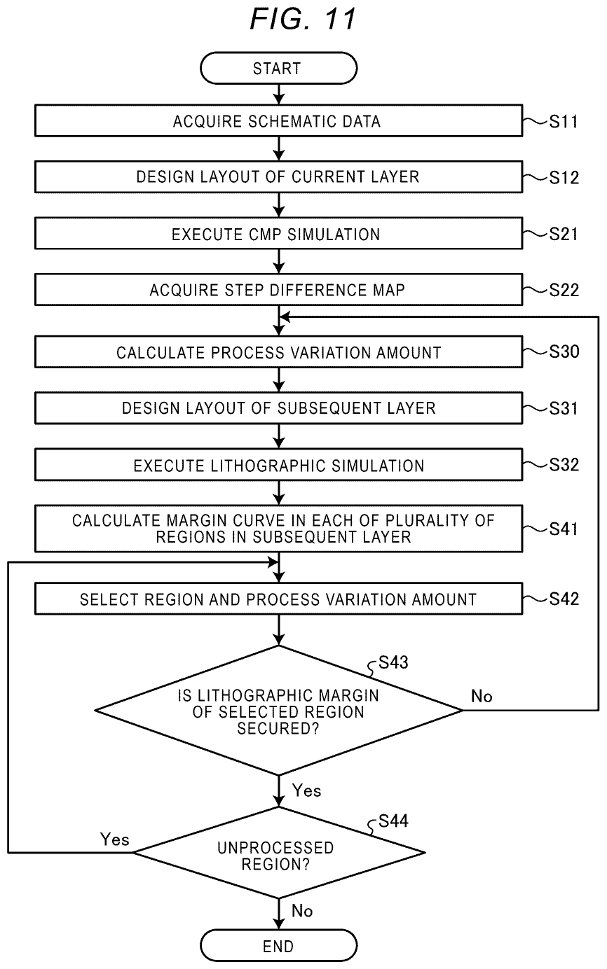

In S3 of FIG. 2, layout design different from that of the first embodiment may be executed at a subsequent point. FIG. 11 is a flowchart illustrating a layout generation method according to the fourth embodiment.

After S11 to S32 are executed similarly to the third embodiment, the simulation device 103 classifies an entire region in the subsequent layer into a plurality of regions in accordance with the step difference map obtained in S22. The simulation device 103 may classify the entire region in the subsequent layer into a plurality of regions in accordance with a level of a step difference indicated by the step difference map.

In the case illustrated in FIGS. 10A and 10B, the simulation device 103 may classify the entire region in the subsequent layer into the main regions RG1 and RG2 with a small step difference, the region RG3 with an intermediate step difference (for example, a step difference ST1), and regions RG4 and RG5 with a large step difference (for example, step differences ST3>ST1).

The simulation device 103 calculates a margin curve in each of the plurality of regions in the subsequent layer (S41).

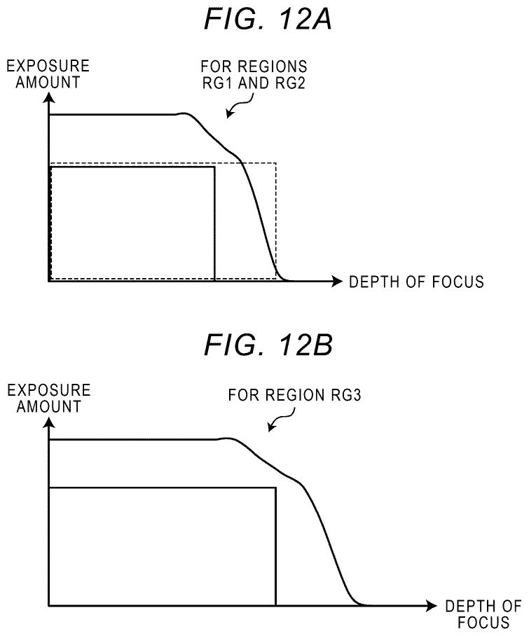

Accordingly, the simulation device 103 can obtain the margin curve that has an exposure amount and a depth of focus as axes, as indicated by solid lines in FIGS. 12A and 12B, in the regions RG1, RG2, and RG3. The curve in FIG. 12A indicates a margin curve for the worst pattern in the main regions RG1 and RG2 with the small step difference. The curve in FIG. 12B indicates a margin curve for the worst pattern in the region RG3 with the intermediate step difference.

The simulation device 103 can set the regions RG4 and RG5 with the large step difference as a region where no pattern is arranged without obtaining the margin curve.

The simulation device 103 selects a processing target region among the plurality of regions in the subsequent layer and selects the process variation amount in accordance with the step difference map (S42). The simulation device 103 may select a process variation amount corresponding to a relatively small step difference for the region with the relatively small step difference, that is, the process variation amount with a small required DOF, in accordance with the step difference map. The simulation device 103 may select a process variation amount corresponding to a relatively large step difference for the region with the relatively large step difference, that is, the process variation amount with a large required DOF, in accordance with the step difference map.

For example, when the main regions RG1 and RG2 with the small step difference are selected as processing target regions, the simulation device 103 uses margin curves for the worst patterns in the regions RG1 and RG2, as illustrated in FIG. 12A, as the margin curves of the regions RG1 and RG2.

When the region RG3 with the intermediate step difference is selected as processing target region, the simulation device 103 uses a margin curve for the worst pattern in the region RG3, as illustrated in FIG. 12B, as the margin curve of the region RG3.

The simulation device 103 determines whether the process variation amount of the selected region falls within the region of the margin curve of the selected region (S43).

For example, when the main regions RG1 and RG2 with the small step difference are selected as processing target regions, the simulation device 103 determines that the process variation amount falls within the region of the margin curve, that is, the lithographic margin is secured when the rectangular region of the process variation amount falls within the region of the margin curve, as illustrated in FIG. 12A.

When the region RG3 with the intermediate step difference is selected as a processing target region, the simulation device 103 determines that the process variation amount falls within the region of the margin curve, that is, the lithographic margin is secured when the rectangular region of the process variation amount falls within the region of the margin curve, as illustrated in FIG. 12B.

When the regions RG4 and RG5 with the large step difference are selected as processing target regions, patterns are arranged in regions where no pattern should be arranged. Therefore, the simulation device 103 can determine that the lithographic margin is not secured.

When the lithographic margin is not secured (No in S43), the layout design device 102 returns the process to S30, calculates the process variation amount in each of the plurality of regions in the subsequent layer (S30), executes the layout design of the subsequent layer again (S31), and changes the layout data of the subsequent layer.

For example, the layout design device 102 changes the arrangement of the pattern in the regions RG4 and RG5 with the large step difference to the main regions RG1 and RG2 with the small step difference or the region RG3 with the intermediate step difference.

After S32 to S43 are executed again, when there is an unprocessed region among plurality of regions in the subsequent layer (Yes in S44), the layout design device 102 returns the process to S42. When there is no unprocessed region (No in S44), the process ends.

In a loop process of S42 to S44, when the process variation amount of at least one region among the plurality of regions in the subsequent layer does not fall within the region of the margin curve of the region, the loop process of S30 to S43 is triggered and the layout data of the subsequent layer is changed.

On the other hand, in the loop process of S42 to S44, when the process variation amount of any region of the plurality of regions in the subsequent layer falls within the region of the margin curve, the loop process of S30 to S43 is not triggered and the layout data of the subsequent layer is allowed as it is. Accordingly, coexistence of the patterns of different line widths between the plurality of regions can be allowed.

As described above, in the layout generation method according to the fourth embodiment, the process variation amount is obtained in each of the plurality of regions in the subsequent layer, and the margin curve is also selected in each of the plurality of regions. Accordingly, it is possible to individually determine whether the process variation amount falls within the region of the margin curve in consideration of the step difference of each of the plurality of regions, and determine whether the appropriate lithographic margin is secured. As a result, it possible to easily improve the degree of freedom of the layout design, such as coexistence of the patterns of different line widths between the plurality of regions.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A method of manufacturing a semiconductor device, the method comprising:
acquiring a process margin of a second layer to be formed on a substrate of the semiconductor device after a first layer is formed on the substrate, based on layout data of the first layer;
executing a process simulation on a computer to determine whether a condition related to the process margin of the second layer falls within an allowable range;
until the condition related to the process margin of the second layer falls within the allowable range, changing the layout data of the first layer and re-executing the process simulation on the computer;
forming a pattern on an original plate using the changed layout data; and
transferring the pattern on the generated original plate to the substrate.

2. The method according to claim 1, wherein the process margin comprises a chemical mechanical polishing (CMP) margin used in connection with a flattening process performed on the second layer.

3. The method according to claim 2, wherein the CMP margin is acquired by further executing the process simulation on the computer to perform a CMP process on the first layer and determining:
a first polishing time in which under-polishing of the first layer occurs,
a second polishing time in which over-polishing of the second layer occurs, and
the CMP margin based on the first polishing time and the second polishing time.

4. The method according to claim 2, wherein the determining includes determining whether the CMP margin falls within the allowable range.

5. The method according to claim 1, wherein the process margin includes a process variation amount of the second layer.

6. The method according to claim 5, wherein the determining includes determining whether the process variation amount of the second layer falls within a region of a margin curve.

7. A method of manufacturing a semiconductor device, the method comprising:
executing a process simulation on a computer to classify a second layer of the semiconductor device formed after a first layer of the semiconductor device into a plurality of regions in accordance with a step difference map of the first layer;
calculating a process variation amount of each of the plurality of regions using layout data of the second layer; and
determining whether the process variation amount falls within a region of a margin curve in each of the plurality of regions;
until the process variation amount falls within the region of the margin curve in each of the regions, changing the layout data of the second layer and re-calculating the process variation amount of each of the plurality of regions;
forming a pattern on an original plate using the changed layout data; and
transferring the pattern on the generated original plate to the substrate.

8. The method according to claim 7, wherein the process variation amount is calculated based on a performance of an exposure device that is used in manufacturing the semiconductor device and the layout data of the second layer.

9. The method according to claim 8, wherein the process variation amount is defined with respect to an exposure amount that is required from the exposure device and a depth of focus that is required from the exposure device.

10. The method according to claim 7, further comprising:
executing a lithographic simulation on the computer in accordance with the step difference map and the layout data of the second layer to determine based on the lithographic simulation whether the process variation amount falls within the region the margin curve in each of the plurality of regions.
